(19) United States
(12) Patent Application Publication
(10) Pub. No.: US 2025/0194305 A1
(43) Pub. Date: Jun. 12, 2025

(54) DISPLAY CHIP AND METHOD FOR MANUFACTURING THE SAME

(71) Applicant: Beijing Zitiao Network Technology Co., Ltd., Beijing (CN)

(72) Inventors: Zhen HUANG, Beijing (CN); Chenggong WANG, Beijing (CN); Duo LI, Beijing (CN); Xiaokai LI, Beijing (CN)

(21) Appl. No.: 18/979,086

(22) Filed: Dec. 12, 2024

(30) Foreign Application Priority Data
Dec. 12, 2023 (CN) 202311707988.0

(51) Int. Cl. H10H 20/841; H10H 20/01; H10H 20/812; H10H 20/819

(52) U.S. Cl. CPC H10H 20/841; H10H 20/017; H10H 20/034; H10H 20/819; H10H 20/812

(57) ABSTRACT

The present application discloses a display chip and a method for manufacturing the same belonging to the technical filed of semiconductor. The display chip includes: a pixel unit, the pixel unit includes a first semiconductor layer, a quantum well light-emitting layer and a second semiconductor layer which are sequentially disposed; one of the first semiconductor layer and the second semiconductor layer is a n-type semiconductor layer, and the other one is a p-type semiconductor layer; wherein a cross-sectional area of the pixel unit is gradually increased in a light emitting direction of the display chip.

### CROSS REFERENCE TO RELATED APPLICATION

This application claims priority from Chinese Patent Application No. 202311707988.0, filed on Dec. 12, 2023, the contents of which are hereby incorporated by reference in their entirety for all purposes.

### TECHNICAL FIELD

The application belongs to the technical field of semiconductors, and particularly relates to a display chip and a method for manufacturing the same.

### BACKGROUND

At present, the difference between the refractive indexes of an epitaxial layer (such as a GaN material layer) and a substrate (such as a sapphire substrate) and air in a display device such as a Micro light-emitting diode (Micro-LED) is large, so that the light extraction efficiency of the display device is low, and the light-emitting performance of the display device is poor.

### SUMMARY

In a first aspect, the present application provides a display chip, including:
a pixel unit, the pixel unit includes a first semiconductor layer, a quantum well light-emitting layer and a second semiconductor layer which are sequentially disposed; one of the first semiconductor layer and the second semiconductor layer is a n-type semiconductor layer, and the other one of the first semiconductor layer and the second semiconductor layer is a p-type semiconductor layer; and a cross-sectional area of the pixel unit is gradually increased in a light emitting direction of the display chip.

According to one embodiment of the application, a longitudinal section of the pixel unit is an isosceles trapezoid.

According to one embodiment of the application, the pixel unit further includes a first transparent conductive layer and a first reflective layer sequentially disposed on one side of the second semiconductor layer facing away from the quantum well light-emitting layer.

According to one embodiment of the application, the display chip further includes a first dielectric layer and a first bonding structure;
the first dielectric layer is located on one side of the first reflective layer facing away from the first transparent conductive layer, and the first bonding structure penetrates through the first dielectric layer and is connected with the first reflective layer.

According to one embodiment of the application, the first bonding structure includes a first bonding layer and a first bonding protective layer;
the first bonding layer penetrates through the first dielectric layer and is connected with the first reflective layer, and the first bonding protective layer is disposed around the first bonding layer.

According to one embodiment of the present application, the display chip further includes a passivation layer and a second reflective layer;
the passivation layer is positioned between the first reflective layer and the first dielectric layer and covers a side wall of the pixel unit, and the second reflective layer covers the passivation layer; the first dielectric layer is positioned on one side of the second reflective layer facing away from the first reflective layer, and the first bonding structure penetrates through the first dielectric layer, the second reflective layer and the passivation layer and is connected with the first reflective layer.

According to one embodiment of the present application, the pixel unit further includes a second undoped semiconductor layer, a first barrier layer, a first superlattice layer, and a second superlattice layer sequentially disposed between the first semiconductor layer and the quantum well light-emitting layer.

According to one embodiment of the present application, the first semiconductor layer includes a heavily doped semiconductor layer and a lightly doped semiconductor layer located between the heavily doped semiconductor layer and the quantum well light-emitting layer.

According to one embodiment of the present application, the quantum well light-emitting layer includes at least one of a blue quantum well light-emitting layer, a green quantum well light-emitting layer, and a red quantum well light-emitting layer;
the blue light quantum well light-emitting layer includes a third undoped semiconductor layer, a first potential well layer, a fourth undoped semiconductor layer and a second potential barrier layer sequentially disposed between the first semiconductor layer and the second semiconductor layer;
the green light quantum well light-emitting layer includes a fifth undoped semiconductor layer, a second potential well layer, a sixth undoped semiconductor layer, a third barrier layer, a seventh undoped semiconductor layer, a third potential well layer, an eighth undoped semiconductor layer and a fourth barrier layer sequentially disposed between the first semiconductor layer and the second semiconductor layer;
the red light quantum well light-emitting layer includes a ninth undoped semiconductor layer, a fourth potential well layer, a first capping layer, a fifth barrier layer, a tenth undoped semiconductor layer, a fifth potential well layer, a second capping layer and a sixth barrier layer sequentially disposed between the first semiconductor layer and the second semiconductor layer.

According to one embodiment of the application, the second semiconductor layer includes an electron blocking layer, a hole injection layer and an ohmic contact layer sequentially disposed on one side of the quantum well light-emitting layer facing away from the first semiconductor layer.

According to one embodiment of the present application, the pixel unit further includes a protective layer between the quantum well light-emitting layer and the second semiconductor layer.

According to one embodiment of the present application, the display chip further includes a base plate, the base plate is in bonding connection with one side of the pixel unit facing away from the first semiconductor layer.

According to one embodiment of the application, the base plate includes a second dielectric layer and a second bonding structure penetrating through the second dielectric layer; the second bonding structure is in bonding connection with the first bonding structure.

According to one embodiment of the application, the second bonding structure includes a second bonding layer and a second bonding protective layer;
the second bonding layer penetrates through the second dielectric layer, and the second bonding protective layer is disposed around the second bonding layer.

According to one embodiment of the present application, the display chip further includes a second transparent conductive layer located on one side of the first semiconductor layer facing away from the second semiconductor layer, and a microlens located on one side of the second transparent conductive layer facing away from the first semiconductor layer.

In a second aspect, the present application provides a method for manufacturing a display chip, including:
forming a base;
forming a pixel unit on one side of the base, wherein the pixel unit includes a first semiconductor layer, a quantum well light-emitting layer and a second semiconductor layer sequentially disposed on the side of the base; one of the first semiconductor layer and the second semiconductor layer is a n-type semiconductor layer, and the other one of the first semiconductor layer and the second semiconductor layer is a p-type semiconductor layer; wherein a cross-sectional area of the pixel unit is gradually increased in a direction toward the base; and
removing the base.

According to one embodiment of the present application, the forming of the pixel unit at one side of the base includes:
forming a first semiconductor layer on one side of the base;
forming a quantum well light-emitting layer on one side of the first semiconductor layer facing away from the base;
forming a second semiconductor layer on one side of the quantum well light-emitting layer facing away from the base; and
etching the second semiconductor layer, the quantum well light-emitting layer and the first semiconductor layer to form the pixel unit.

According to one embodiment of the application, the first semiconductor layer includes a heavily doped semiconductor layer and a lightly doped semiconductor layer positioned between the heavily doped semiconductor layer and the quantum well light-emitting layer;
the etching the second semiconductor layer, the quantum well light-emitting layer and the first semiconductor layer to form the pixel unit includes:
etching the second semiconductor layer, the quantum well light-emitting layer and the lightly doped semiconductor layer to form an initial pixel unit, and exposing part of the heavily doped semiconductor layer;
forming a passivation layer on one side of the initial pixel unit facing away from the base, and the passivation layer covers a side wall of the initial pixel unit and the exposed part of the heavily doped semiconductor layer;
forming a second reflective layer on a surface of the passivation layer; and
etching the second reflective layer, the passivation layer and the heavily doped semiconductor layer on a peripheral side of the initial pixel unit to form the pixel unit.

According to one embodiment of the present application, before the removing said base, further including:
bonding one side of the pixel unit facing away from the base, with a base plate.

According to one embodiment of the application, the pixel unit further includes a first transparent conductive layer and a first reflective layer sequentially disposed on one side of the second semiconductor layer facing away from the quantum well light-emitting layer, and the base plate includes a second bonding structure;
bonding one side of the pixel unit facing away from the base, with a base plate includes:
forming a first dielectric layer on one side of the first reflective layer facing away from the first transparent conductive layer;
forming a first bonding structure penetrating through the first dielectric layer and is connected with the first reflective layer; and
bonding the pixel unit and the base plate through the first bonding structure and the second bonding structure.

According to one embodiment of the application, the first bonding structure includes a first bonding layer and a first bonding protective layer;
the forming a first bonding structure penetrating through the first dielectric layer and connected with the first reflective layer includes:
forming an opening penetrating through the first dielectric layer; forming the first bonding protective layer on a side wall of the opening; forming the first bonding layer connected with the first reflective layer in the opening.

According to one embodiment of the present application, after the removing the base, the method further including:
forming a second transparent conductive layer on one side of the pixel unit facing away from the second semiconductor layer; and
forming a micro lens on one side of the second transparent conductive layer facing away from the pixel unit.

Additional aspects and advantages of the application will be set forth in part in the description which follows and, in part, will be obvious from the description, or may be learned by practice of the application.

### BRIEF DESCRIPTION OF THE DRAWINGS

The above and/or additional aspects and advantages of the present application will become apparent and readily appreciated from the following description of the embodiments, taken in conjunction with the accompanying drawings of which:

FIG. 1 is a schematic flow chart of a method for manufacturing a display chip according to one embodiment of the present application;

FIG. 2 is a first schematic structural diagram of a display chip in a manufacturing process according to one embodiment of the present application;

FIG. 3 is a second schematic structural diagram of a display chip in a manufacturing process according to one embodiment of the present application;

FIG. 4 is a third schematic structural diagram of a display chip in a manufacturing process according to one embodiment of the present application;

FIG. 5 is a fourth schematic structural diagram of a display chip in a manufacturing process according to one embodiment of the present application;

FIG. 6 is a fifth schematic structural diagram of a display chip in a manufacturing process according to one embodiment of the present application;

FIG. 7 is a sixth schematic structural diagram of a display chip in a manufacturing process according to one embodiment of the present application;

FIG. 8 is a seventh schematic structural diagram of a display chip in a manufacturing process according to one embodiment of the present application;

FIG. 9 is an eighth schematic structural diagram of a display chip in a manufacturing process according to one embodiment of the present application;

FIG. 10 is a ninth schematic structural diagram of a display chip in a manufacturing process according to one embodiment of the present application;

FIG. 11 is a tenth schematic structural diagram of a display chip in a manufacturing process according to one embodiment of the present application;

FIG. 12 is an eleventh schematic structural diagram of a display chip in a manufacturing process according to one embodiment of the present application;

FIG. 13 is a twelfth schematic structural diagram of a display chip in a manufacturing process according to one embodiment of the present application;

FIG. 14 is a thirteen schematic structural diagram of a display chip in a manufacturing process according to one embodiment of the present application;

FIG. 15 is a fourteenth schematic structural diagram of a display chip in a manufacturing process according to one embodiment of the present application;

FIG. 16 is a schematic structural diagram of a display chip according to one embodiment of the present application.

### DETAILED DESCRIPTION

Reference will now be made in detail to embodiments of the present application, examples of which are illustrated in the accompanying drawings, wherein like reference numerals refer to the same or similar elements or elements having the same or similar functions throughout. The embodiments described below with reference to the accompanying drawings are illustrative only for the purpose of explaining the present application and are not to be construed as limiting the present application.

The following describes a display chip and a method for manufacturing the same provided by one embodiment of the application with reference to the accompanying drawings.

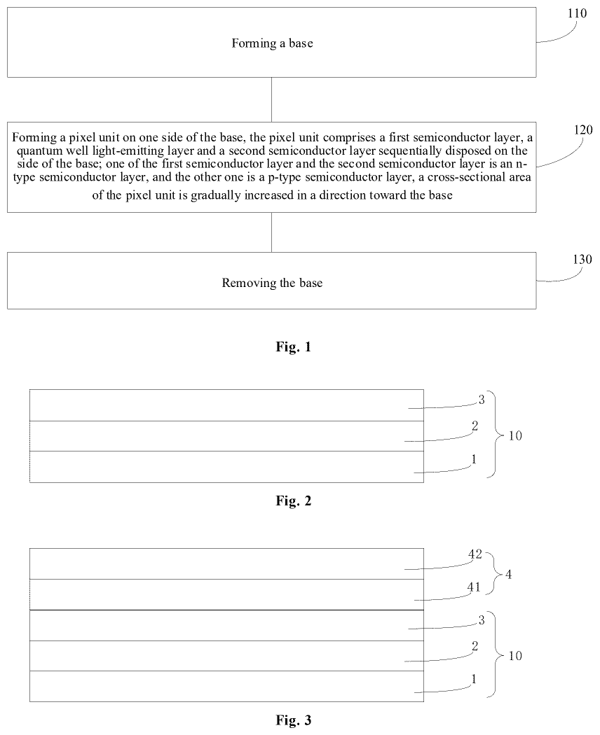

FIG. 1 is a schematic flow chart of a method for manufacturing a display chip according to one embodiment of the present application. The display chip can be a Micro-LED display chip.

As shown in FIG. 1, the method for manufacturing the display chip according to the embodiment of the present application includes steps 110 to 130.

Step 110, forming a base.

In some embodiments, as shown in FIG. 2, the base 10 may include the substrate 1, a buffer layer 2, and an undoped semiconductor layer 3. Forming a base in step 110 includes: providing a substrate 1; forming the buffer layer 2 on one side of the substrate 1; forming the undoped semiconductor layer 3 on the buffer layer 2 on the side facing away from the substrate 1.

The substrate 1 may include a c-plane sapphire substrate, a Si substrate, a n-SiC substrate, a n-GaN bulk substrate, or the like.

When the substrate 1 includes a c-plane sapphire substrate or a n-GaN homogeneous substrate, the buffer layer 2 may include an AIN buffer layer, the buffer layer 2 may have a thickness of 15 nm-50 nm, the undoped semiconductor layer 3 may include a u-GaN layer, and the undoped semiconductor layer 3 may have a thickness of 2 μm-4 μm.

The buffer layer 2 is deposited on one side of the substrate 1 using, for example, a PVD (Physical Vapor Deposition) apparatus. Then, depositing the undoped semiconductor layer 3 on one side of the buffer layer 2 facing away from the substrate 1, by using MOCVD (Metal Organic Chemical Vapor Deposition) apparatus, wherein the temperature of a reaction chamber is 1040-1080° C. The buffer layer 2 and the undoped semiconductor layer 3 may be formed by other processes, and are not specifically limited herein.

In some embodiments, the base 10 further includes a graded buffer layer between the buffer layer 2 and the undoped semiconductor layer 3. For example, when the substrate 1 includes a Si substrate or a n-SiC substrate, the base 10 further includes the graded buffer layer.

When the substrate 1 includes the Si substrate, the buffer layer 2 may include an AlN buffer layer, the graded buffer layer may include a graded AlGaN layer, and the undoped semiconductor layer 3 may include a u-GaN layer.

When the substrate 1 includes the n-SiC substrate, the buffer layer 2 may include a n-AlGaN buffer layer, the graded buffer layer may include the graded AlGaN layer, and the undoped semiconductor layer 3 may include the u-GaN layer.

For example, using the MOCVD apparatus, the buffer layer 2, the graded buffer layer, and the undoped semiconductor layer 3 are sequentially grown on one side of the substrate 1. The buffer layer 2, the graded buffer layer, and the undoped semiconductor layer 3 may be formed by other processes, and are not specifically limited herein.

Step 120, forming a pixel unit on one side of the base, wherein the pixel unit includes a first semiconductor layer, a quantum well light-emitting layer and a second semiconductor layer sequentially disposed on one side of the base; one of the first semiconductor layer and the second semiconductor layer is a n-type semiconductor layer, and the other of the first semiconductor layer and the second semiconductor layer is a p-type semiconductor layer; wherein the cross-sectional area of the pixel unit gradually increases in a direction toward the base.

As shown in FIGS. 3 to 10, the pixel unit 20 includes a first semiconductor layer 4, a quantum well light-emitting layer 5, and a second semiconductor layer 6. Forming the pixel unit on one side of the base in step 120 includes: forming the first semiconductor layer 4 on one side of a base 10; forming the quantum well light-emitting layer 5 on one side of the first semiconductor layer 4 facing away from the base 10; forming the second semiconductor layer 6 on the side of the quantum well light-emitting layer 5 facing away from the first semiconductor layer 4; etching the second semiconductor layer 6, the quantum well light-emitting layer 5, and the first semiconductor layer 4 to form the pixel unit 20.

The first semiconductor layer 4 is a n-type semiconductor layer, and the second semiconductor layer 6 is a p-type semiconductor layer. Alternatively, the first semiconductor layer 4 is a p-type semiconductor layer, and the second semiconductor layer 6 is a n-type semiconductor layer.

In the direction A toward the base 10, the cross-sectional area of the pixel unit 20 gradually increases, that is, in the pixel unit 20, the cross-sectional area of the first semiconductor layer 4 is larger than the cross-sectional area of the quantum well light-emitting layer 5, and the cross-sectional area of the quantum well light-emitting layer 5 is larger than the cross-sectional area of the second semiconductor layer 6.

In the present embodiment, the cross-sectional area of the pixel unit 20 gradually increases in a direction A toward the base 10 (i.e., a light emitting direction of the display chip), so as to reduce a light emitting divergence angle of the display chip, improve light extraction efficiency of the display chip, and further improve light efficiency of the display chip.

In some embodiments, the pixel unit 20 may be formed by one-step etch, that is, by etching the first semiconductor layer 4, the quantum well light-emitting layer 5, and the second semiconductor layer 6 simultaneously to form the pixel unit 20. The longitudinal section of the pixel unit 20 may be an isosceles trapezoid.

In some embodiments, the pixel unit 20 may be formed by two-step etching, that is, by etching a part of the film layer in the first semiconductor layer 4, the quantum well light-emitting layer 5, and the second semiconductor layer 6, and then etching the remaining film layer, to form the pixel unit 20, so as to prevent the etching effect from being affected by the excessive thickness of the entire film layer.

As shown in conjunction with FIGS. 3 to 10, the first semiconductor layer 4 includes a heavily doped semiconductor layer 41 and a lightly doped semiconductor layer 42. The heavily doped semiconductor layer 41 is located on the side of the base 10, e.g., the heavily doped semiconductor layer 41 is located on the side of the undoped semiconductor layer 3 facing away from the substrate 1, and the lightly doped semiconductor layer 42 is located on the side of the heavily doped semiconductor layer 41 facing away from the base 10.

The step of etching the second semiconductor layer 6, the quantum well light-emitting layer 5, and the first semiconductor layer 4 to form the pixel unit 20 includes: etching the second semiconductor layer 6, the quantum well light-emitting layer 5 and the lightly doped semiconductor layer 42 to form an initial pixel unit 20′, and exposing a part of the heavily doped semiconductor layer 41; forming a passivation layer 81 on a side of the initial pixel unit 20′ facing away from the base 10, and the passivation layer 81 covers the side wall and the exposed part of the heavily doped semiconductor layer 41 of the initial pixel unit 20′; forming a second reflective layer 82 on a surface of the passivation layer 81; the second reflective layer 82, the passivation layer 82, and the heavily doped semiconductor layer 41 at the peripheral side of the initial pixel unit 20′ are etched to form the pixel unit 20.

In this embodiment, the pixel unit 20 is formed by two-step etching processes, that is, the second semiconductor layer 6, the quantum well light-emitting layer 5 and the lightly doped semiconductor layer 42 are etched first, and then the heavily doped semiconductor layer 41 is etched to form the pixel unit 20.

For example, as shown in FIG. 3, the step of forming the first semiconductor layer on one side of the base includes: forming a heavily doped semiconductor layer 41 on one side of the transition layer 3 facing away from the substrate 1; forming a lightly doped semiconductor layer 42 on the side of the heavily doped semiconductor layer 41 facing away from the transition layer 3.

The heavily doped semiconductor layer 41 can include a n-GaN heavily doped layer, the electron concentration of the heavily doped semiconductor layer 41 is 1×10¹⁸ cm⁻³-2×10¹⁹ cm⁻³, and the thickness of the heavily doped semiconductor layer 41 is 1.5 μm-2 μm.

The heavily doped semiconductor layer 41 can also include a n-Al_{c}Ga_{1-c}N/n-GaN superlattice layer, 0.05≤c≤0.1, and the electron concentration is 1×10¹⁸ cm⁻³-2×10¹⁹ cm⁻³. Wherein the Al component in the n-Al_{c}Ga_{1-c}N is about 5%-10%, the thickness can be 2 nm-3 nm, and the thickness of the n-GaN can be 2.5 nm-15 nm. The n-Al_{c}Ga_{1-c}N/n-GaN superlattice layer can relieve dislocation extension and stress regulation.

For example, the temperature of the reaction chamber is 1040° C.-1080° C., SiH₄ is selected as a n-type dopant of the GaN layer, and a heavily doped semiconductor layer 41 is grown on the side of the undoped semiconductor layer 3 facing away from the substrate 1.

The lightly doped semiconductor layer 42 may include a n-GaN lightly doped layer, the electron concentration of the lightly doped semiconductor layer 42 is 1×10¹⁷ cm⁻³-5×10¹⁷ cm⁻³, and the thickness of the lightly doped semiconductor layer 42 is 0.2 μm-0.5 μm.

The lightly doped semiconductor layer 42 can also include a n-Al_{g}Ga_{1-g}N/n-GaN superlattice layer, 0.02≤g≤0.08, and the electron concentration can be 1×10¹⁷ cm⁻³-5×10¹⁷ cm⁻³. Wherein, the Al component in the n-Al_{g}Ga_{1-g}N is about 2%-8%, the thickness can be 2 nm-3 nm, and the thickness of the n-GaN can be 2.5 nm-15 nm.

For example, the temperature of the reaction chamber is 1040° C.-1080° C., SiH₄ is selected as a n-type dopant of the GaN layer, and the lightly doped semiconductor layer 42 is grown on the side of the heavily doped semiconductor layer 41 facing away from the undoped semiconductor layer 3.

It should be noted that the heavily doped semiconductor layer 41 and the lightly doped semiconductor layer 42 may also be formed by other processes, and are not limited herein.

In some embodiments, as shown in conjunction with FIGS. 4-10, the pixel unit 20 further includes a fourth undoped semiconductor layer 71, a first barrier layer 72, a first superlattice layer 73, and a second superlattice layer 74.

For example, as shown in FIG. 4, before the step of forming the quantum well light-emitting layer on the side of the first semiconductor layer facing away from the base, the method further includes: sequentially forming the fourth undoped semiconductor layer 71, the first barrier layer 72, the first superlattice layer 73 and the second superlattice layer 74 on the side of the first semiconductor layer 4 facing away from the base 10, and the quantum well light-emitting layer 5 is located on the side of the second superlattice layer 74 facing away from the first superlattice layer 73.

The fourth undoped semiconductor layer 71 may include a u-GaN layer, and the thickness of the fourth undoped semiconductor layer 71 may be 10 nm-30 nm. The first barrier layer 72 may include a GaN layer, and the thickness of the first barrier layer 72 may be 10 nm-30 nm. The first superlattice layer 73 may include at least one period (e.g., 1-3 periods) of u-InₐGa₁₋ₐN/u-GaN superlattice layer, and 0.01≤a≤0.05. The thickness of the u-InₐGa₁₋ₐN can be 2 nm-3 nm, the In component is 1%-5%, and the thickness of the u-GaN can be 2.5 nm-15 nm. The second superlattice layer 74 may include at least one period (e.g., 1-3 periods) of u-In_{b}Ga_{1-b}N/n-GaN superlattice layer, and 0.05≤b≤0.08. The electron concentration of the n-GaN can be 1×10¹⁷ cm⁻³-5×10¹⁷ cm⁻³, the thickness of the u-In_{b}Ga_{1-b}N can be 2 nm-3 nm, the In component can be 5%-8%, and the thickness of the n-GaN can be 2.5 nm-15 nm.

For example, after the lightly doped semiconductor layer 42 is grown, the temperature of the reaction chamber is reduced to 900° C.-1000° C., and the fourth undoped semiconductor layer 71 is grown on the side of the lightly doped semiconductor layer 42 facing away from the heavily doped semiconductor layer 41. The fourth undoped semiconductor layer 71 is used for repairing damage from hydrogen etching in the temperature reduction process.

The atmosphere for growing the above film layers is hydrogen atmosphere, then the temperature of the reaction chamber is reduced to 800-900° C., and the atmosphere is switched to the nitrogen atmosphere, and the first barrier layer 72 is grown on the side of the fourth undoped semiconductor layer 71 facing away from the lightly doped semiconductor layer 42. Then, the first superlattice layer 73 is grown on a side of the first barrier layer 72 facing away from the fourth undoped semiconductor layer 71. The growth of the second superlattice layer 74 continues on the side of the first superlattice layer 73 facing away from the first barrier layer 72.

The fourth undoped semiconductor layer 71, the first barrier layer 72, the first superlattice layer 73, and the second superlattice layer 74 may also be formed by other processes, which are not specifically limited herein.

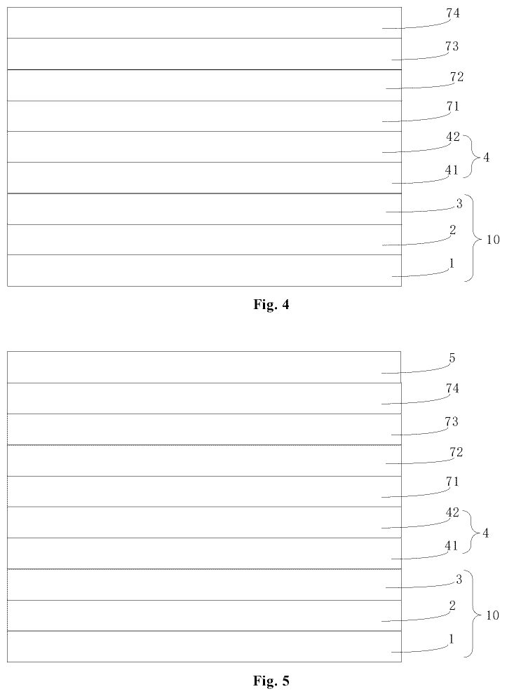

Then, as shown in FIG. 5, the quantum well light-emitting layer 5 is formed on the side of the second superlattice layer 74 facing away from the first superlattice layer 73.

In some embodiments, the quantum well light-emitting layer 5 includes at least one of a blue, green, and red quantum well light-emitting layer.

In some embodiments, the blue quantum well light-emitting layer includes a third undoped semiconductor layer, a first potential well layer, a fourth undoped semiconductor layer, and a second barrier layer, which are sequentially disposed between the second superlattice layer 74 and the second semiconductor layer 6.

The third undoped semiconductor layer and the fourth undoped semiconductor layer can both include u-GaN layers, and the third undoped semiconductor layer and the fourth undoped semiconductor layer can both have a thickness of 2 nm-3 nm. The first potential well layer can include a u-InⱼGa₁₋ⱼN layer, 0.15≤j≤0.2, and the thickness of the first potential well layer can be 2.5 nm-3.5 nm. The second barrier layer may include a u-InₖGa₁₋ₖN layer, 0.01≤k≤0.02, and the thickness of the second barrier layer may be 10 nm-15 nm.

In some embodiments, the green quantum well light-emitting layer can include a fifth undoped semiconductor layer, a second potential well layer, a sixth undoped semiconductor layer, a third barrier layer, a seventh undoped semiconductor layer, a third potential well layer, an eighth undoped semiconductor layer, and a fourth barrier layer which are sequentially disposed between the second superlattice layer 74 and the second semiconductor layer.

In some embodiments, the green quantum well light-emitting layer includes at least one first periodic structure (e.g., 1-2 first periodic structures) and at least one second periodic structure (e.g., 2-3 second periodic structures). The first periodic structure can include a fifth undoped semiconductor layer, a second potential well layer, a sixth undoped semiconductor layer, and a third barrier layer, and the second periodic structure can include a seventh undoped semiconductor layer, a third potential well layer, an eighth undoped semiconductor layer, and a fourth barrier layer.

The fifth undoped semiconductor layer to the eighth undoped semiconductor layer may include a u-GaN layer, and the fifth undoped semiconductor layer to the eighth undoped semiconductor layer may have a thickness of 2 nm-3 nm. The second potential well layer includes a u-InₘGa₁₋ₘN layer, 0.22≤m≤0.25, and the thickness of the second potential well layer can be 2.5 nm-3.5 nm. The third barrier layer may include a n-GaN layer, the electron concentration may be 1×10¹⁷ cm⁻³-5×10¹⁷ cm⁻³, and the thickness of the third barrier layer may be 10 nm-15 nm. The third potential well layer may include a u-InₚGa₁₋ₚN layer, 0.25≤p≤0.28, and the thickness of the third potential well layer can be 2.5 nm-3.5 nm. The fourth barrier layer includes a n-GaN layer, the electron concentration can be 1×10¹⁷ cm⁻³-5×10¹⁷ cm⁻³, and the thickness of the fourth barrier layer can be 10 nm-15 nm. It should be noted that the growth mode in the green quantum well light-emitting layer can effectively alleviate the wavelength shift (shift) problem under the large current injection.

In some embodiments, the red quantum well light-emitting layer includes at least one third periodic structure (e.g., 2-3 periodic structures), each third periodic structure including a ninth undoped semiconductor layer, a fourth potential well layer, a first cap layer, a fifth barrier layer, a tenth undoped semiconductor layer, a fifth potential well layer, a second cap layer, and a sixth barrier layer which are sequentially disposed between the second superlattice layer 74 and the second semiconductor layer 6.

The ninth undoped semiconductor layer may include a low-temperature u-GaN layer, and the thickness of the ninth undoped semiconductor layer may be 2 nm-3 nm. The fourth potential well layer can include a u-InₓGa₁₋ₓN layer, 0.1≤x≤0.15, and the thickness of the fourth potential well layer can be 2.5 nm-3.5 nm. The first cap layer can include a GaN layer, and the thickness of the first cap layer can be 2 nm-3 nm. The fifth barrier layer can include a GaN layer or a u-In_{y}Ga_{1-y}N layer, 0.01≤y≤0.03, and the thickness of the fifth barrier layer can be 10 nm-15 nm. The tenth undoped semiconductor layer may include a low-temperature u-GaN layer, and the thickness of the tenth undoped semiconductor layer may be 2 nm-3 nm. The fifth potential well layer can include a u-In_{z}Ga_{1-z}N layer, 0.35≤z≤0.4, and the thickness of the fifth potential well layer can be 2.5 nm-3.5 nm. The second cap layer can include a GaN layer, and the thickness of the second cap layer can be 2 nm-3 nm. The sixth barrier layer can include a u-Al_{d}Ga_{1-d}N layer, 0.3≤d≤0.35, and the thickness of the sixth barrier layer can be 10 nm-15 nm.

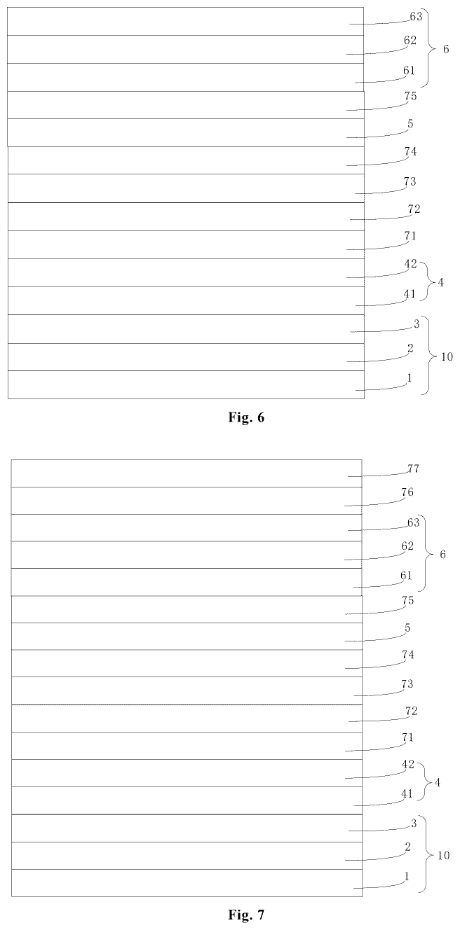

In some embodiments, as shown in conjunction with FIGS. 6-10, the pixel unit 20 further includes a protective layer 75.

For example, as shown in FIG. 6, before the step of forming the second semiconductor layer 6 on the side of the quantum well light-emitting layer 5 facing away from the base 10, the method further includes: forming a protective layer 75 on the side of the quantum well light-emitting layer 5 facing away from the first semiconductor layer 4, and the second semiconductor layer 6 is located on the side of the protective layer 75 facing away from the quantum well light-emitting layer 5.

The protective layer 75 may include a u-GaN layer, and the thickness of the protective layer 75 may be 20 nm-50 nm.

For example, in a nitrogen atmosphere, the protective layer 75 is grown on the side of the quantum well light-emitting layer 5 facing away from the first semiconductor layer 4. The protective layer 75 is used to protect the quantum well light-emitting layer 5 when the hydrogen atmosphere is switched subsequently.

Then, as shown in FIG. 6, the second semiconductor layer 6 is formed on the side of the protective layer 75 facing away from the quantum well light-emitting layer 5.

In some embodiments, the second semiconductor layer 6 includes an electron blocking layer 61, a hole injection layer 62 and an ohmic contact layer 63 sequentially formed on the side of the quantum well light-emitting layer 5 facing away from the first semiconductor layer 4.

The electron blocking layer 61 can include a p-AlGaN polarization inducing layer, the thickness of the p-AlGaN polarization inducing layer can be 50 nm-60 nm, the Al component can be linearly reduced to 0 from 30%, and the theoretical calculated film layer hole concentration is 2.5×10¹⁸ cm⁻³. It should be noted that p-AlGaN is generally used as the electron blocking layer 61, but in this material system, the activation energy of doped Mg is high, and it is difficult to achieve high hole concentration and low resistivity. Therefore, the electron blocking layer 61 in this embodiment employs a p-AlGaN polarization inducing layer, and the differential resistance of the device can be reduced.

The electron blocking layer 61 can also include a p-AlₑGa₁₋ₑN/p-GaN superlattice layer, 0.1≤e≤0.3, the Al component in the p-AlₑGa₁₋ₑN is about 10%-30%, the thickness of the p-AlₑGa₁₋ₑN can be 2 nm-3 nm, and the thickness of the p-GaN can be 2.5 nm-15 nm.

The hole injection layer 62 may include a p-GaN layer, and the thickness of the hole injection layer 62 may be 80 nm-200 nm. The hole injection layer 62 can also include a p-AlₕGa₁₋ₕN/p-GaN superlattice layer, 0.15≤h≤0.25, and the hole concentration can be 1.5×10¹⁸ cm⁻³-2.5×10¹⁸ cm⁻³. The Al component in the p-AlₕGa₁₋ₕN is about 15%-25%, the thickness of the p-AlₕGa₁₋ₕN can be 2 nm-3 nm, and the thickness of the p-GaN can be 2.5 nm-15 nm.

The ohmic contact layer 63 may include at least one period (e.g., 4-6 periods) of p-In_{f}Ga_{1-f}N/p-GaN superlattice layer, 0.1≤f≤0.2. Wherein the In component In the p-In_{f}Ga_{1-f}N is about 10%-20%, the thickness of the p-In_{f}Ga_{1-f}N can be 2 nm-3 nm, and the thickness of the p-GaN can be 2.5 nm-15 nm.

For example, the hydrogen atmosphere is switched and the electron blocking layer 61 is grown on the side of the protective layer 75 facing away from the quantum well light-emitting layer 5. A hole-injection layer 62 is then deposited on the side of the electron blocking layer 61 facing away from the protective layer 75. An ohmic contact layer 63 is deposited on the side of the hole injection layer 62 facing away from the electron blocking layer 61.

In some embodiments, as shown in conjunction with FIGS. 7-10, the pixel unit 20 further includes a first transparent conductive layer 76 and a first reflective layer 77.

For example, as shown in FIG. 7, before the step of etching the second semiconductor layer 6, the quantum well light-emitting layer 5, and the first semiconductor layer 4, the method further includes: sequentially forming the first transparent conductive layer 76 and the first reflective layer 77 on the side of the second semiconductor layer 6 facing away from the quantum well light-emitting layer 5. The first reflective layer 77 serves to enhance the light extraction efficiency of the display chip.

The first transparent conductive layer 76 may include an ITO (Indium Tin Oxide) layer, and the thickness of the first transparent conductive layer 76 may be 50 nm-200 nm. The first reflective layer 77 may include a metal reflective layer, for example, including at least one of Ag and Al, and the thickness of the first reflective layer 77 may be 100 nm-300 nm.

For example, an electron beam evaporation or PVD process is used to deposit the first transparent conductive layer 76 on the side of the ohmic contact layer 63 facing away from the hole injection layer 62, and an annealing process is combined to increase the transmittance of the first transparent conductive layer 76 and reduce the material resistance. The first reflective layer 77 is then deposited on the side of the first transparent conductive layer 76 facing away from the ohmic contact layer 63 using an electron beam evaporation or PVD process.

It should be noted that the first transparent conductive layer 76 and the first reflective layer 77 may be formed by other processes, and are not specifically limited herein.

In some embodiments, the pixel unit 20 may be formed by one-step etching. The first semiconductor layer 4, the fourth undoped semiconductor layer 71, the first barrier layer 72, the first superlattice layer 73, the second superlattice layer 74, the quantum well light-emitting layer 5, the second semiconductor layer 6, the first transparent conductive layer 76 and the first reflective layer 77 are simultaneously etched, so as to obtain the pixel unit 20. In the pixel unit 20, the cross-sectional areas of the first semiconductor layer 4, the fourth undoped semiconductor layer 71, the first barrier layer 72, the first superlattice layer 73, the second superlattice layer 74, the quantum well light-emitting layer 5, the second semiconductor layer 6, the first transparent conductive layer 76, and the first reflective layer 77 are gradually reduced.

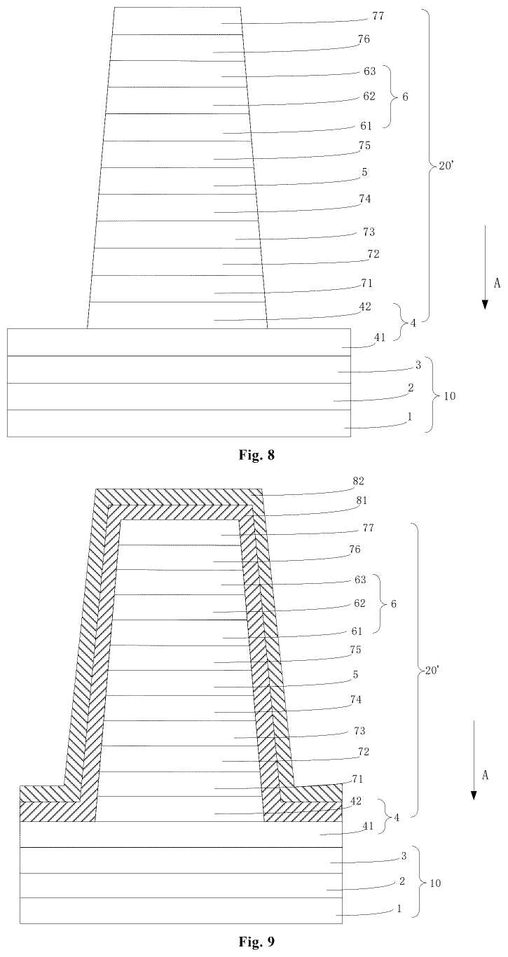

In some embodiments, the pixel unit 20 may be formed by two-step etchings. As shown in FIG. 8, the lightly doped semiconductor layer 42 in the first semiconductor layer 4, the fourth undoped semiconductor layer 71, the first barrier layer 72, the first superlattice layer 73, the second superlattice layer 74, the quantum well light-emitting layer 5, the second semiconductor layer 6, the first transparent conductive layer 76, and the first reflective layer 77 are etched to obtain an initial pixel unit 20′. In the initial pixel unit 20′, the cross-sectional areas of the lightly doped semiconductor layer 42, the fourth undoped semiconductor layer 71, the first barrier layer 72, the first superlattice layer 73, the second superlattice layer 74, the quantum-well light-emitting layer 5, the second semiconductor layer 6, the first transparent conductive layer 76, and the first reflective layer 77 are gradually reduced. It should be noted that, at this time, the heavily doped semiconductor layer 41 in the first semiconductor layer 4 is not etched, and a surface of the side of the heavily doped semiconductor layer 41 facing away from the base 10 is partially exposed, that is, a part of the heavily doped semiconductor layer 41 is exposed.

For example, a photoresist (PR) is deposited, exposed using a yellow light process, and etched using an ICP (Inductively Coupled Plasma) process to form an initial pixel unit 20′, and then a photoresist removing process is performed.

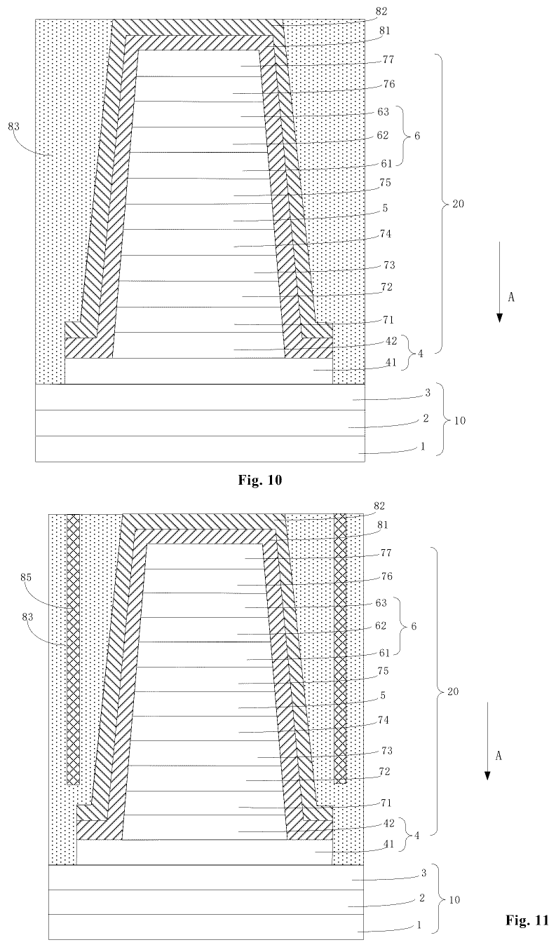

Then, as shown in FIG. 9, a passivation layer 81 is formed on a side of the first reflective layer 77 facing away from the first transparent conductive layer 76, and the passivation layer 81 covers the sidewalls of the initial pixel unit 20′ and the exposed portion of the heavily doped semiconductor layer 41. Then, the surface of the passivation layer 81 is covered with a second reflective layer 82. The second reflective layer 82 may further enhance the light extraction efficiency of the chip.

The passivation layer 81 may include at least one of SiO₂, SiNₓ, and Al₂O₃, and the thickness of the passivation layer 81 may be 10 nm-40 nm. The second reflective layer 82 may include a DBR (Distributed Bragg Reflector) layer, which may include TiO₂/SiO₂ or Ta₂O₅/SiO₂, among others.

For example, the sidewalls of the initial pixel unit 20′ are repaired using a wet etch (e.g., TMAH (tetramethylammonium hydroxide) solution) and the passivation layer 81 is deposited using an ALD (Atomic Layer Deposition) apparatus. The second reflective layer 82 is then deposited using PVD, electron beam evaporation, or ALD apparatus.

For another example, the passivation layer 81 may be deposited by plasma processing the sidewalls of the initial pixel unit 20′ using a PE-ALD apparatus. The gases may include O₂, Ar, H₂, NH₃, N₂, and the like. The second reflective layer 82 is then deposited using PVD, electron beam evaporation, or ALD apparatus.

As another example, a protective layer is deposited on the initial pixel unit 20′ by a photolithography process using a PECVD process. The protective layer may include a SiO₂ layer, and the thickness of the protective layer may be 10 nm-40 nm. The passivation layer 81 is deposited by plasma processing the sidewalls of the initial pixel unit 20′ with a PE-ALD apparatus, gases that may include O₂, Ar, H₂, NH₃, N₂, etc. The second reflective layer 82 is then deposited using PVD, electron beam evaporation, or ALD apparatus.

It should be noted that other processes may also be used to form the passivation layer 81 and the second reflective layer 82, which is not limited herein.

Then, as shown in FIG. 10, the second reflective layer 82, the passivation layer 81, and the heavily doped semiconductor layer 41 at the peripheral side of the initial pixel unit 20′ are etched to form the pixel unit 20. The etching process may include a photolithography process and an ICP process. In the pixel unit 20, the cross-sectional areas of the heavily doped semiconductor layer 41, the lightly doped semiconductor layer 42, the fourth undoped semiconductor layer 71, the first barrier layer 72, the first superlattice layer 73, the second superlattice layer 74, the quantum well light-emitting layer 5, the second semiconductor layer 6, the first transparent conductive layer 76, and the first reflective layer 77 are gradually reduced.

In some embodiments, as shown in FIG. 10, the method for manufacturing the display chip further includes: forming an isolation layer 83 on the peripheral side of the pixel unit 20. The isolation layer 83 covers the base 10, and a surface of the isolation layer 83 facing away from the base 10 is flush with a surface of the second reflective layer 82 facing away from the base 10. Wherein the isolation layer 83 may include at least one of SiO₂ and SiNₓ.

For example, the spacer 83 is deposited on the peripheral side of the pixel unit 20 using a PECVD apparatus. It should be noted that the isolation layer 83 may also be formed by other processes, and is not limited herein.

In some embodiments, as shown in FIG. 11, the method for manufacturing the display chip further includes: forming a groove in the spacer 83 and forming a third reflective layer 85 in the groove. The third reflective layer 85 is located on the peripheral side of the pixel unit 20, and the third reflective layer 85 can reduce crosstalk between pixels and a divergence angle of outgoing light, and improve light extraction efficiency.

Among them, the third reflective layer 85 may include a metal layer, such as including at least one of Ag and Al, etc.

For example, a photoresist is deposited, and a recess is etched in the isolation layer 83 using an exposure process and an etching process in sequence. Then, a third reflective layer 85 is deposited in the groove using an electron beam evaporation or PVD process. Finally, the photoresist and the third reflective layer 85 on the photoresist are removed using an acetone solution.

The third reflective layer 85 may also be formed by other processes, and is not limited herein.

In some embodiments, after the step of forming the pixel unit, the method for manufacturing the display chip further includes:
bonding one side of the pixel unit facing away from the base, with a base plate.

Wherein the base plate may include a silicon substrate or a silicon-based Complementary Metal Oxide Semiconductor (CMOS) pixel driving backplane.

In some embodiments, the step of bonding the side of the pixel unit facing away from the base, with the base plate includes: forming a first dielectric layer on one side of the first reflective layer facing away from the first transparent conductive layer; forming a first bonding structure penetrating through the first dielectric layer and connected with the first reflective layer; and bonding the pixel unit and the base plate through the first bonding structure and the second bonding structure.

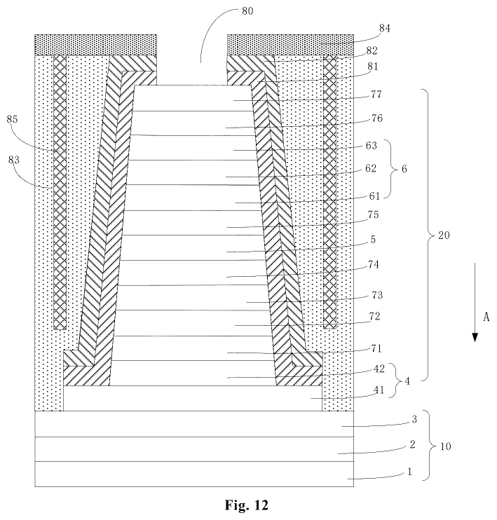

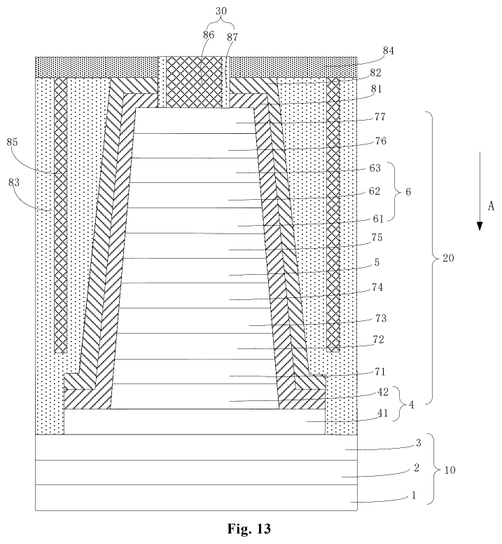

As shown in FIGS. 12 and 13, in the case where the first reflective layer 77 has a passivation layer 81 and a second reflective layer 82 on a side facing away from the first transparent conductive layer 76, and the pixel unit 20 has an isolation layer 83 on a peripheral side thereof, a first dielectric layer 84 is formed on a side of the second reflective layer 82 facing away from the base 10 and on a side of the isolation layer 83 facing away from the base 10. Then, the first bonding structure 30 penetrating through the first dielectric layer 84, the second reflective layer 82, and the passivation layer 81 and connected to the first reflective layer 77 is formed. The first dielectric layer 84 may include at least one of SiO₂ and SiNₓ, and the thickness of the first dielectric layer 84 may be 100 nm-200 nm.

In some embodiments, the first bonding structure 30 may include a first bonding layer 86 and a first bonding protective layer 87. A step of forming a first bonding structure penetrating through the first dielectric layer and connected to the first reflective layer, including: forming an opening penetrating through the first dielectric layer; forming a first bonding protective layer on the side wall of the opening; forming a first bonding layer connected with the first reflective layer in the opening.

As shown in FIG. 12, an opening 80 is formed penetrating through the first dielectric layer 84, the second reflective layer 82, and the passivation layer 81. As shown in FIG. 13, a first bonding protective layer 87 is formed on the sidewall of the opening 80, and then the opening 80 is filled with a first bonding layer 86. The first bonding protective layer 87 may include a TiN layer, and the first bonding layer 86 may include a metal layer, such as Ni/Au, Pt/Au, Cu, or the like.

For example, the first dielectric layer 84 is deposited by using a PECVD apparatus, then a photoresist is deposited, and the opening 80 is etched by using an exposure process and an etching process to expose the first reflective layer 77. Then, a photoresist is deposited, a first bonding protective layer 87 is deposited on the sidewalls of the opening 80 using a physical and chemical vapor deposition process, and the photoresist is removed. Then, a first bonding layer 86 is deposited in the opening 80 by using an electron beam evaporation or PVD process, and a CMP (Chemical Mechanical Polishing) process is performed to make a surface of the first bonding structure 30 facing away from the base 10 flush with a surface of the first dielectric layer 84 facing away from the base 10. It should be noted that the first dielectric layer 84 and the first bonding structure 30 may also be formed by other processes, which are not limited herein.

The present embodiment improves the bonding accuracy between the pixel unit 20 and other base plates by providing the first bonding structure 30.

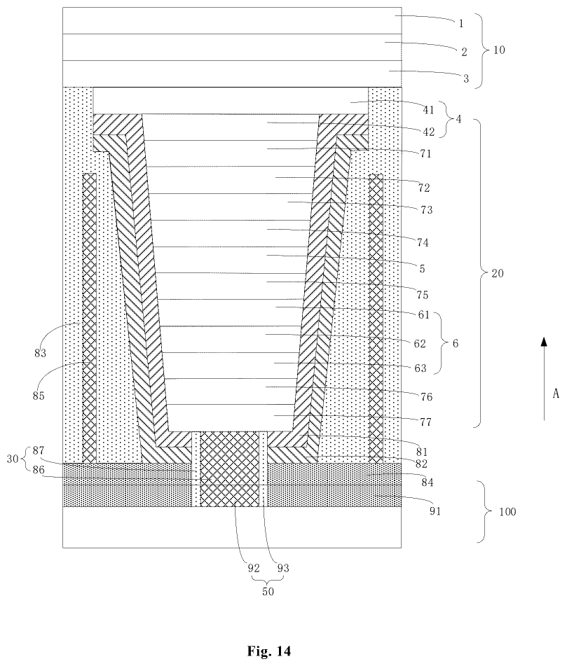

As shown in FIG. 14, the base plate 100 is located on a side of the first dielectric layer 84 facing away from the first semiconductor layer 4, and the pixel unit 20 is in bonding connection with the base plate 100 through the first bonding structure 30.

In some embodiments, the base plate 100 may include a second dielectric layer 91 and a second bonding structure 50 penetrating through the second dielectric layer 91, and the second bonding structure 50 is in bonding connection with the first bonding structure 30.

In some embodiments, the second bonding structure 50 includes a second bonding layer 92 and a second bonding protective layer 93 disposed around the second bonding layer 92. The second bonding protective layer 93 may include a TiN layer, and the second bonding layer 92 may include a metal layer, such as Ni/Au, Pt/Au, or Cu.

The present embodiment improves the bonding accuracy between the pixel unit 20 and the base plate 100 by providing the first bonding structure 30 and the second bonding structure 50.

Step 130, removing the base.

The base 10 may include the substrate 1, the buffer layer 2, and the undoped semiconductor layer 3.

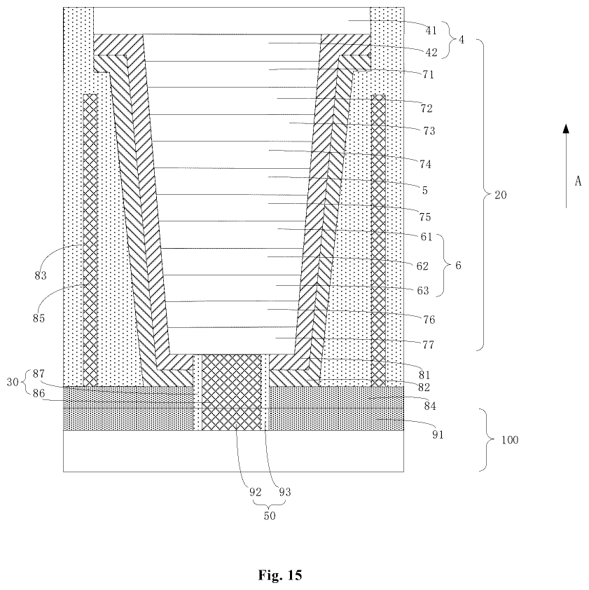

As shown in FIG. 15, the removing the base in step 130 includes: removing the substrate 1; removing the buffer layer 2 and the undoped semiconductor layer 3.

For example, when the substrate 1 is a sapphire substrate, the substrate 1 is removed by a laser lift-off technique. Wherein the selected pulse laser wavelength can be 355 nm, 266 nm and 248 nm. When the substrate 1 is a Si substrate, the substrate 1 is removed by a wet etching method. When the substrate 1 is a n-SiC substrate, the substrate 1 is removed by wet etching, grinding or ICP-RIE (inductively coupled plasma-reactive ion etching) etching. When the substrate 1 is a n-GaN homogeneous substrate, the substrate 1 is removed by grinding or ICP-RIE etching.

Then, the buffer layer 2 and the undoped semiconductor layer composite layer 3 are etched by an ICP-RIE process until the heavily doped semiconductor layer 41 is exposed.

In some embodiments, after the step of removing the base, the method further includes: forming a second transparent conductive layer on one side of the pixel unit facing away from the second semiconductor layer; and forming a micro lens on one side of the second transparent conductive layer facing away from the pixel unit.

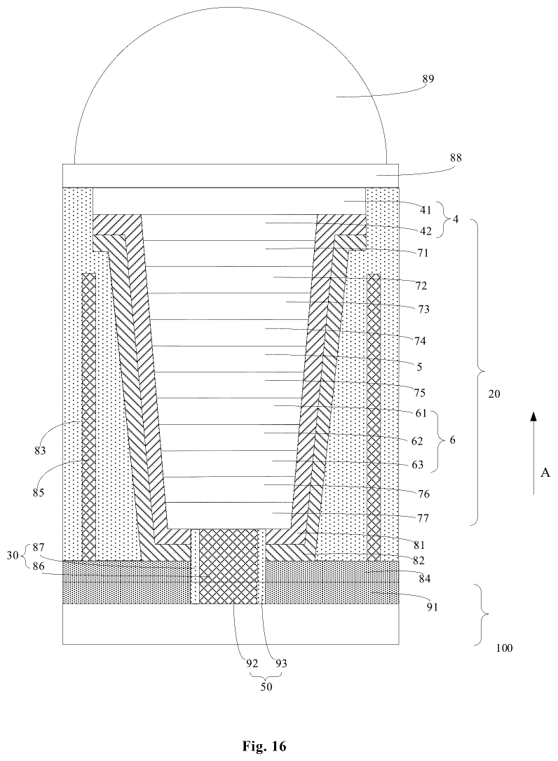

As shown in FIG. 16, a second transparent conductive layer 88 is formed on the side of the heavily doped semiconductor layer 41 facing away from the lightly doped semiconductor layer 42. The second transparent conductive layer 88 may include an ITO layer, and the thickness of the second transparent conductive layer 88 may be 100 nm-400 nm.

For example, the heavily doped semiconductor layer 41 is subjected to surface roughening treatment by using a dry etching or wet etching process. Then, the second transparent conductive layer 88 is deposited by using an electron beam evaporation or PVD process, and an annealing process is combined to improve the transmittance of the second transparent conductive layer 88 and reduce the material resistance. It should be noted that the second transparent conductive layer 88 can also be formed by other processes, and is not limited herein.

Then, microlenses 89 (micro-lenses) are formed on a side of the second transparent conductive layer 88 facing away from the base plate 100, and the microlenses 89 correspond to the positions of the pixel units 20. The microlenses 89 are used to increase the light collection of the chip. The microlens 85 includes SiO₂ and the like.

For example, the microlenses 87 are deposited using a PECVD apparatus. It should be noted that the microlenses 87 may be formed by other processes, and are not limited herein.

In order to obtain a high-luminance display chip, it is necessary to improve the internal quantum efficiency and the external quantum efficiency of the chip. Among them, the main factor restricting the external quantum efficiency is that the light extraction efficiency of the chip is low because the refractive index of the GaN material (n=2.5) in the epitaxial layer is greatly different from the refractive index of air (n=1) and the refractive index of the substrate (e.g., the refractive index n=1.75 of the sapphire substrate), resulting in the critical angles of total reflection at the interface between air and GaN and the interface between the substrate and GaN being only 23.6° and 44.4°, respectively. Thus, only a few of the light generated by the quantum well active region can escape from the bulk material.

In order to improve the light extraction efficiency of the display chip, currently, related technologies include a patterned substrate (PSS) technology, a surface roughening technology, a plasmon excimer and a photonic crystal technology. However, the PSS technique has high requirements for the substrate process, while the sapphire substrate is relatively hard, which has certain difficulties in ensuring the uniformity and uniformity of the pattern, resulting in high cost. The plasma excimer and photonic crystal technology is relatively complex, and the complexity of the manufacturing process is increased.

According to the embodiment of the application, the geometric outline of the pixel unit is reshaped, so that the cross-sectional area of the pixel unit is gradually increased in the light-emitting direction of the display chip, the light-emitting divergence angle of the display chip is reduced, the light extraction efficiency of the display chip is improved, the light efficiency of the display chip is further improved, the cost is prevented from being increased, and the process complexity is prevented from being increased. Moreover, the first bonding structure and the second bonding structure are adopted for realizing high-precision bonding of the pixel unit and the base plate.

Correspondingly, the embodiment of the application also provides a display chip which can be manufactured by adopting the method for manufacturing the display chip. The display chip can be a Micro-LED display chip.

As shown in FIG. 16, the display chip includes a pixel unit 20, the pixel unit 20 includes the first semiconductor layer 4, the quantum well light-emitting layer 5, and the second semiconductor layer 6, the quantum well light-emitting layer 5 is located on one side of the first semiconductor layer 4, and the second semiconductor layer 6 is located on one side of the quantum well light-emitting layer 5 facing away from the first semiconductor layer 4.

One of the first semiconductor layer 4 and the second semiconductor layer 6 is a n-type semiconductor layer, and the other is a p-type semiconductor layer, that is, the first semiconductor layer 4 is a n-type semiconductor layer, and the second semiconductor layer 6 is a p-type semiconductor layer; alternatively, the first semiconductor layer 4 is a p-type semiconductor layer, and the second semiconductor layer 6 is a n-type semiconductor layer.

In the light emitting direction A toward the display chip, the cross-sectional area of the pixel unit 20 gradually increases, that is, the cross-sectional area of the first semiconductor layer 4 is larger than that of the quantum well light-emitting layer 5, and the cross-sectional area of the quantum well light-emitting layer 5 is larger than that of the second semiconductor layer 6.

The cross-sectional area of the pixel unit in this embodiment is gradually increased in the light-emitting direction towards the display chip to reduce the light-emitting divergence angle of the display chip, to improve the light extraction efficiency of the display chip, and further improve the light efficiency of the display chip.

In some embodiments, the longitudinal cross-section of the pixel unit 20 is an isosceles trapezoid.

In some embodiments, the pixel unit 20 further includes a first transparent conductive layer 76 and a first reflective layer 77 sequentially disposed on a side of the second semiconductor layer 6 facing away from the quantum well light-emitting layer 5, that is, the first transparent conductive layer 76 is disposed on a side of the second semiconductor layer 6 facing away from the quantum well light-emitting layer 5, and the first reflective layer 77 is disposed on a side of the first transparent conductive layer 76 facing away from the second semiconductor layer 6. The cross-sectional area of the first transparent conductive layer 76 is larger than that of the first reflective layer 77, and the cross-sectional area of the second semiconductor layer 6 is larger than that of the first transparent conductive layer 76. The first reflective layer 77 serves to enhance the light extraction efficiency of the display chip.

The first transparent conductive layer 76 may include an ITO (indium tin oxide) layer, and the thickness of the first transparent conductive layer 76 may be 50 nm-200 nm. The first reflective layer 77 may include a metal reflective layer, for example, including at least one of Ag and Al, and the thickness of the first reflective layer 77 may be 100 nm-300 nm.

In some embodiments, the display chip further includes a first dielectric layer 84 and a first bonding structure 30. The first dielectric layer 84 is located on a side of the first reflective layer 77 facing away from the first transparent conductive layer 76, and the first bonding structure 30 penetrates through the first dielectric layer 84 and is connected to the first reflective layer 77. The first dielectric layer 84 may include at least one of SiO₂ and SiNₓ, and the thickness of the first dielectric layer 84 may be 100 nm-200 nm.

In some embodiments, the first bonding structure 30 includes a first bonding layer 86 and a first bonding protective layer 87. The first bonding layer 86 penetrates through the first dielectric layer 84 and is connected to the first reflective layer 77, and a first bonding protective layer 87 is disposed around the first bonding layer 86. The first bonding protective layer 87 may include a TiN layer, and the first bonding layer 86 may include a metal layer, such as Ni/Au, Pt/Au, Cu, or the like.

The present embodiment improves the bonding accuracy between the pixel unit 20 and other base plates by providing the first bonding structure 30.

In some embodiments, the display chip further includes a passivation layer 81 and a second reflective layer 82. The passivation layer 81 is located between the first reflective layer 77 and the first dielectric layer 84 and covers the sidewalls of the pixel unit 20, and the second reflective layer 82 is located between the passivation layer 81 and the first dielectric layer 84 and covers the passivation layer 81, i.e., the second reflective layer 82 is located on the surface of the passivation layer 81. The second reflective layer 82 may further enhance the light extraction efficiency of the chip.

The passivation layer 81 may include at least one of SiO₂, SiNₓ, and Al₂O₃, and the thickness of the passivation layer 81 may be 10 nm-40 nm. The second reflective layer 82 may include a DBR (Distributed Bragg Reflector) layer, which may include TiO₂/SiO₂ or Ta₂O₅/SiO₂, among others.

In some embodiments, the pixel unit 20 further includes a fourth undoped semiconductor layer 71, a first barrier layer 72, a first superlattice layer 73, and a second superlattice layer 74. The fourth undoped semiconductor layer 71, the first barrier layer 72, the first superlattice layer 73, and the second superlattice layer 74 are sequentially disposed between the first semiconductor layer 4 and the quantum well light-emitting layer 5.

The cross-sectional areas of the fourth undoped semiconductor layer 71, the first barrier layer 72, the first superlattice layer 73, and the second superlattice layer 74 are gradually reduced. Further, the cross-sectional area of the fourth undoped semiconductor layer 71 is smaller than the cross-sectional area of the first semiconductor layer 4, and the cross-sectional area of the second superlattice layer 74 is larger than the cross-sectional area of the quantum well light-emitting layer 5.

The fourth undoped semiconductor layer 71 may include a u-GaN layer, and the thickness of the fourth undoped semiconductor layer 71 may be 10 nm-30 nm. The first barrier layer 72 may include a GaN layer, and the thickness of the first barrier layer 72 may be 10 nm-30 nm. The first superlattice layer 73 may include at least one period (e.g., 1-3 periods) of u-InₐGa₁₋ₐN/u-GaN superlattice layer, and 0.01≤a≤0.05. The thickness of the u-InₐGa₁₋ₐN can be 2 nm-3 nm, the In component is 1%-5%, and the thickness of the u-GaN can be 2.5 nm-15 nm. The second superlattice layer 74 may include at least one period (e.g., 1-3 periods) of u-In_{b}Ga_{1-b}N/n-GaN superlattice layer, and 0.05≤b≤0.08. The electron concentration of the n-GaN can be 1×10¹⁷ cm⁻³-5×10¹⁷ cm⁻³, the thickness of the u-In_{b}Ga_{1-b}N can be 2 nm-3 nm, the In component can be 5%-8%, and the thickness of the n-GaN can be 2.5 nm-15 nm.

In some embodiments, the first semiconductor layer 4 includes a heavily doped semiconductor layer 41 and a lightly doped semiconductor layer 42. The lightly doped semiconductor layer 42 is located between the heavily doped semiconductor layer 41 and the quantum well light-emitting layer 5, and the lightly doped semiconductor layer 42 is located between the heavily doped semiconductor layer 41 and the fourth undoped semiconductor layer 71. The cross-sectional area of the heavily doped semiconductor layer 41 is larger than that of the lightly doped semiconductor layer 42. Also, the cross-sectional area of the lightly doped semiconductor layer 42 is larger than that of the fourth undoped semiconductor layer 71.

The heavily doped semiconductor layer 41 can include a n-GaN heavily doped layer, the electron concentration of the heavily doped semiconductor layer 41 is 1×10¹⁸ cm⁻³-2×10¹⁹ cm⁻³, and the thickness of the heavily doped semiconductor layer 41 is 1.5 μm-2 μm.

The heavily doped semiconductor layer 41 can also include a n-Al_{c}Ga_{1-c}N/n-GaN superlattice layer, 0.05≤c≤0.1, and the electron concentration is 1×10¹⁸ cm⁻³-2×10¹⁹ cm⁻³. Wherein the Al component in the n-Al_{c}Ga_{1-c}N is about 5%-10%, the thickness can be 2 nm-3 nm, and the thickness of the n-GaN can be 2.5 nm-15 nm. The n-Al_{c}Ga_{1-c}N/n-GaN superlattice layer can relieve dislocation extension and stress regulation.

The lightly doped semiconductor layer 42 may include a n-GaN lightly doped layer, the electron concentration of the lightly doped semiconductor layer 42 is 1×10¹⁷ cm⁻³-5×10¹⁷ cm⁻³, and the thickness of the lightly doped semiconductor layer 42 is 0.2 μm-0.5 μm.

The lightly doped semiconductor layer 42 can also include a n-Al_{g}Ga_{1-g}N/n-GaN superlattice layer, 0.02≤g≤0.08, and the electron concentration can be 1×10¹⁷ cm⁻³-5×10¹⁷ cm⁻³. Wherein, the Al component in the n-Al_{g}Ga_{1-g}N is about 2%-8%, the thickness can be 2 nm-3 nm, and the thickness of the n-GaN can be 2.5 nm-15 nm.

In some embodiments, quantum well light-emitting layer 5 includes at least one of a blue, green, and red quantum well light-emitting layer.

In some embodiments, the blue quantum-well light-emitting layer includes a third undoped semiconductor layer, a first potential well layer, a fourth undoped semiconductor layer, and a second barrier layer which are sequentially disposed between the first semiconductor layer 4 and the second semiconductor layer 6 (e.g., between the second superlattice layer 74 and the second semiconductor layer 6).

The third undoped semiconductor layer and the fourth undoped semiconductor layer can both include u-GaN layers, and the third undoped semiconductor layer and the fourth undoped semiconductor layer can both have a thickness of 2 nm-3 nm. The first potential well layer can include a u-InⱼGa₁₋ⱼN layer, 0.15≤j≤0.2, and the thickness of the first potential well layer can be 2.5 nm-3.5 nm. The second barrier layer may include a u-InₖGa₁₋ₖN layer, 0.01≤k≤0.02, and the thickness of the second barrier layer may be 10 nm-15 nm.

In some embodiments, the green quantum-well light-emitting layer can include a fifth undoped semiconductor layer, a second potential well layer, a sixth undoped semiconductor layer, a third barrier layer, a seventh undoped semiconductor layer, a third potential well layer, an eighth undoped semiconductor layer, and a fourth barrier layer which are sequentially disposed between the first semiconductor layer 4 and the second semiconductor layer 6 (e.g., between the second superlattice layer 74 and the second semiconductor layer 6).

In some embodiments, the green quantum well light-emitting layer includes at least one first periodic structure (e.g., 1-2 first periodic structures) and at least one second periodic structure (e.g., 2-3 second periodic structures). The first periodic structure can include a fifth undoped semiconductor layer, a second potential well layer, a sixth undoped semiconductor layer, and a third barrier layer, and the second periodic structure can include a seventh undoped semiconductor layer, a third potential well layer, an eighth undoped semiconductor layer, and a fourth barrier layer.

The fifth undoped semiconductor layer to the eighth undoped semiconductor layer may include a u-GaN layer, and the fifth undoped semiconductor layer to the eighth undoped semiconductor layer may have a thickness of 2 nm-3 nm. The second potential well layer includes a u-InₘGa₁₋ₘN layer, 0.22≤m≤0.25, and the thickness of the second potential well layer can be 2.5 nm-3.5 nm. The third barrier layer may include a n-GaN layer, the electron concentration may be 1×10¹⁷ cm⁻³-5×10¹⁷ cm⁻³, and the thickness of the third barrier layer may be 10 nm-15 nm. The third potential well layer may include a u-InₚGa₁₋ₚN layer, 0.25≤p≤0.28, and the thickness of the third potential well layer can be 2.5 nm-3.5 nm. The fourth barrier layer includes a n-GaN layer, the electron concentration can be 1×10¹⁷ cm⁻³-5×10¹⁷ cm⁻³, and the thickness of the fourth barrier layer can be 10 nm-15 nm. It should be noted that the growth mode in the green quantum well light-emitting layer can effectively alleviate the wavelength shift (shift) problem under the large current injection.

In some embodiments, the red quantum well light-emitting layer includes at least one third periodic structure (e.g., 2-3 periodic structures), each third periodic structure including a ninth undoped semiconductor layer, a fourth potential well layer, a first capping layer, a fifth barrier layer, a tenth undoped semiconductor layer, a fifth potential well layer, a second capping layer, and a sixth barrier layer sequentially disposed between the first semiconductor layer 4 and the second semiconductor layer 6 (e.g., between the second superlattice layer 74 and the second semiconductor layer 6).

The ninth undoped semiconductor layer may include a low-temperature u-GaN layer, and the thickness of the ninth undoped semiconductor layer may be 2 nm-3 nm. The fourth potential well layer can include a u-InₓGa₁₋ₓN layer, 0.1≤x≤0.15, and the thickness of the fourth potential well layer can be 2.5 nm-3.5 nm. The first cap layer can include a GaN layer, and the thickness of the first cap layer can be 2 nm-3 nm. The fifth barrier layer can include a GaN layer or a u-In_{y}Ga_{1-y}N layer, 0.01≤y≤0.03, and the thickness of the fifth barrier layer can be 10 nm-15 nm. The tenth undoped semiconductor layer may include a low-temperature u-GaN layer, and the thickness of the tenth undoped semiconductor layer may be 2 nm-3 nm. The fifth potential well layer can include a u-In_{z}Ga_{1-z}N layer, 0.35≤z≤0.4, and the thickness of the fifth potential well layer can be 2.5 nm-3.5 nm. The second cap layer can include a GaN layer, and the thickness of the second cap layer can be 2 nm-3 nm. The sixth barrier layer can include a u-Al_{d}Ga_{1-d}N layer, 0.3≤d≤0.35, and the thickness of the sixth barrier layer can be 10 nm-15 nm.

In some embodiments, the second semiconductor layer 6 includes an electron blocking layer 61, a hole injection layer 62 and an ohmic contact layer 63, which are sequentially disposed on a side of the quantum well light-emitting layer 5 facing away from the first semiconductor layer 4, that is, the electron blocking layer 61 is located on a side of the quantum well light-emitting layer 5 facing away from the first semiconductor layer 4, the hole injection layer 62 is located on a side of the electron blocking layer 61 facing away from the quantum well light-emitting layer, and the ohmic contact layer 63 is located on a side of the hole injection layer 62 facing away from the electron blocking layer 61. The cross-sectional areas of the electron blocking layer 61, the hole injection layer 62, and the ohmic contact layer 63 are gradually reduced. Also, the cross-sectional area of the electron blocking layer 61 is smaller than that of the quantum well light-emitting layer 5.

The electron blocking layer 61 can include a p-AlGaN polarization inducing layer, the thickness of the p-AlGaN polarization inducing layer can be 50 nm-60 nm, the Al component can be linearly reduced to 0 from 30%, and the theoretical calculated film layer hole concentration is 2.5×10¹⁸ cm⁻³. It should be noted that p-AlGaN is generally used as the electron blocking layer 61, but in this material system, the activation energy of doped Mg is high, and it is difficult to achieve high hole concentration and low resistivity. Therefore, the electron blocking layer 61 in this embodiment employs a p-AlGaN polarization inducing layer, and the differential resistance of the device can be reduced.

The electron blocking layer 61 can also include a p-AlₑGa₁₋ₑN/p-GaN superlattice layer, 0.1≤e≤0.3, the Al component in the p-AlₑGa₁₋ₑN is about 10%-30%, the thickness of the p-AlₑGa₁₋ₑN can be 2 nm-3 nm, and the thickness of the p-GaN can be 2.5 nm-15 nm.

The hole injection layer 62 may include a p-GaN layer, and the thickness of the hole injection layer 62 may be 80 nm-200 nm. The hole injection layer 62 can also include a p-AlₕGa₁₋ₕN/p-GaN superlattice layer, 0.15≤h≤0.25, and the hole concentration can be 1.5×10¹⁸ cm⁻³-2.5×10¹⁸ cm⁻³. The Al component in the p-AlₕGa₁₋ₕN is about 15%-25%, the thickness of the p-AlₕGa₁₋ₕN can be 2 nm-3 nm, and the thickness of the p-GaN can be 2.5 nm-15 nm.

The ohmic contact layer 63 may include at least one period (e.g., 4-6 periods) of p-In_{f}Ga_{1-f}N/p-GaN superlattice layer, 0.1≤f≤0.2. Wherein the In component In the p-In_{f}Ga_{1-f}N is about 10%-20%, the thickness of the p-In_{f}Ga_{1-f}N can be 2 nm-3 nm, and the thickness of the p-GaN can be 2.5 nm-15 nm.

In some embodiments, the pixel unit 20 further includes a protective layer 75, and the protective layer 75 is located between the quantum-well light-emitting layer 5 and the second semiconductor layer 6, i.e., the protective layer 75 is located between the quantum-well light-emitting layer 5 and the electron blocking layer 61. The cross-sectional area of protective layer 75 is smaller than the cross-sectional area of quantum well light-emitting layer 5, and the cross-sectional area of protective layer 75 is larger than the cross-sectional area of electron blocking layer 61.

The protective layer 75 may include a u-GaN layer, and the thickness of the protective layer 75 may be 20 nm-50 nm.

In some embodiments, the display chip further includes a base plate 100, and the base plate 100 is in bonding connection with a side of the pixel unit 20 facing away from the first semiconductor layer 4.

In some embodiments, the base plate 100 is located on a side of the first dielectric layer 84 facing away from the first semiconductor layer 4, and the base plate 100 is in bonding connection with the pixel unit 20 through the first bonding structure 30. The base plate 100 may include a silicon substrate or a silicon-based Complementary Metal Oxide Semiconductor (CMOS) pixel driving backplane, among others.

In a direction A away from the base plate 100 (i.e., a light emitting direction of the display chip), the cross-sectional area of the pixel unit 20 gradually increases.

In this embodiment, the cross-sectional area of the pixel unit 20 is gradually increased in the direction A away from the base plate 100, so as to reduce the light-emitting divergence angle of the display chip, improve the light extraction efficiency of the display chip, and further improve the light efficiency of the display chip.

In some embodiments, the base plate 100 includes a second dielectric layer 91 and a second bonding structure 50 penetrating through the second dielectric layer 91, and the second bonding structure 50 is in bonding connection with the first bonding structure 30.

The embodiment realizes the bonding connection between the pixel unit 20 and the base plate 100 through the first bonding structure 30 and the second bonding structure 50, and improves the bonding precision.

In some embodiments, the second bonding structure 50 includes a second bonding layer 92 and a second bonding protective layer 93, the second bonding layer 92 penetrates through the second dielectric layer 91, and the second bonding protective layer 93 is disposed around the second bonding layer 92. The second bonding protective layer 93 may include a TiN layer, and the second bonding layer 92 may include a metal layer, such as Ni/Au, Pt/Au, or Cu.

In some embodiments, the display chip further includes a second transparent conductive layer 88, and the second transparent conductive layer 88 is located on a side of the first semiconductor layer 4 facing away from the second semiconductor layer 5, i.e. the second transparent conductive layer 88 is located on a side of the heavily doped semiconductor layer 41 facing away from the lightly doped semiconductor layer 42. The second transparent conductive layer 88 may include an ITO layer, and the thickness of the second transparent conductive layer 88 may be 100 nm-400 nm.

In some embodiments, the display chip further includes a microlens 85, the microlens 85 is located on a side of the second transparent conductive layer 88 facing away from the base plate 100, and the microlens 89 corresponds to a position of the pixel unit 20. The microlenses 89 are used to increase the light collection of the chip. The microlens 85 includes SiO₂ and the like.

According to the display chip provided by the embodiment of the application, the geometric outline of the pixel unit 20 is reshaped, so that the cross-sectional area of the pixel unit 20 is gradually increased in the light emitting direction A away from the display chip, the light emitting divergence angle of the display chip is reduced, the light extraction efficiency of the display chip is improved, the light efficiency of the display chip is further improved, and the high-precision bonding of the pixel unit 20 and the base plate 100 is realized through the first bonding structure 30 and the second bonding structure 50.

The terms “first”, “second” and the like in the description and in the claims are used for distinguishing between similar elements and not necessarily for describing a particular sequential or chronological order. It will be appreciated that the data so used may be interchanged under appropriate circumstances such that embodiments of the application may be practiced other than those illustrated or described herein, and that the words “first”, “second”, etc. do not necessarily distinguish one element from another, but rather denote any number of elements, e.g., a first element may be one or more than one. In the description of the present application, “a plurality” means two or more.

In the description of the present specification, reference to the description of “one embodiment”, “some embodiments”, “an illustrative embodiment”, “an example”, “a specific example” or “some examples” or the like means that a particular feature, structure, material, or characteristic described in connection with the embodiment or example is included in at least one embodiment or example of the present application. In this specification, the schematic representations of the terms used above do not necessarily refer to the same embodiment or example. Furthermore, the particular features, structures, materials, or characteristics described may be combined in any suitable manner in any one or more embodiments or examples.

While embodiments of the present application have been shown and described, it will be understood by those of ordinary skill in the art that: various changes, modifications, substitutions and alterations can be made to the embodiments without departing from the principles and spirit of the application, the scope of which is defined by the claims and their equivalents.

What is claimed is:

1. A display chip, comprising:
a pixel unit, the pixel unit comprises a first semiconductor layer, a quantum well light-emitting layer and a second semiconductor layer which are sequentially disposed; one of the first semiconductor layer and the second semiconductor layer is a n-type semiconductor layer, and the other one of the first semiconductor layer and the second semiconductor layer is a p-type semiconductor layer;
wherein a cross-sectional area of the pixel unit is gradually increased in a light emitting direction of the display chip.

2. The display chip according to claim 1, wherein a longitudinal section of the pixel unit is an isosceles trapezoid.

3. The display chip according to claim 1, wherein the pixel unit further comprises a first transparent conductive layer and a first reflective layer sequentially disposed on one side of the second semiconductor layer facing away from the quantum well light-emitting layer.

4. The display chip according to claim 3, wherein the display chip further comprises a first dielectric layer and a first bonding structure;
the first dielectric layer is located on one side of the first reflective layer facing away from the first transparent conductive layer, and the first bonding structure penetrates through the first dielectric layer and is connected with the first reflective layer.

5. The display chip according to claim 4, wherein the first bonding structure comprises a first bonding layer and a first bonding protective layer;
the first bonding layer penetrates through the first dielectric layer and is connected with the first reflective layer, and the first bonding protective layer is disposed around the first bonding layer.

6. The display chip according to claim 4, wherein the display chip further comprises a passivation layer and a second reflective layer;
the passivation layer is positioned between the first reflective layer and the first dielectric layer and covers a side wall of the pixel unit, and the second reflective layer covers the passivation layer; the first dielectric layer is positioned on one side of the second reflective layer facing away from the first reflective layer, and the first bonding structure penetrates through the first dielectric layer, the second reflective layer and the passivation layer and is connected with the first reflective layer.

7. The display chip according to claim 1, wherein the first semiconductor layer comprises a heavily doped semiconductor layer and a lightly doped semiconductor layer located between the heavily doped semiconductor layer and the quantum well light-emitting layer.

8. The display chip according to claim 1, wherein the quantum well light-emitting layer comprises at least one of a blue quantum well light-emitting layer, a green quantum well light-emitting layer, and a red quantum well light-emitting layer;
the blue light quantum well light-emitting layer comprises a third undoped semiconductor layer, a first potential well layer, a fourth undoped semiconductor layer and a second potential barrier layer sequentially disposed between the first semiconductor layer and the second semiconductor layer;
the green light quantum well light-emitting layer comprises a fifth undoped semiconductor layer, a second potential well layer, a sixth undoped semiconductor layer, a third barrier layer, a seventh undoped semiconductor layer, a third potential well layer, an eighth undoped semiconductor layer and a fourth barrier layer sequentially disposed between the first semiconductor layer and the second semiconductor layer;
the red light quantum well light-emitting layer comprises a ninth undoped semiconductor layer, a fourth potential well layer, a first capping layer, a fifth barrier layer, a tenth undoped semiconductor layer, a fifth potential well layer, a second capping layer and a sixth barrier layer sequentially disposed between the first semiconductor layer and the second semiconductor layer.

9. The display chip according to claim 1, wherein the second semiconductor layer comprises an electron blocking layer, a hole injection layer and an ohmic contact layer sequentially disposed on one side of the quantum well light-emitting layer facing away from the first semiconductor layer.

10. The display chip according to claim 4, wherein the display chip further comprises:
a base plate, the base plate is in bonding connection with one side of the first dielectric layer facing away from the first semiconductor layer.

11. The display chip according to claim 10, wherein the base comprises a second dielectric layer and a second bonding structure penetrating through the second dielectric layer;
the second bonding structure is in bonding connection with the first bonding structure.

12. The display chip according to claim 11, wherein the second bonding structure comprises a second bonding layer and a second bonding protective layer;
the second bonding layer penetrates through the second dielectric layer, and the second bonding protective layer is disposed around the second bonding layer.

13. The display chip according to claim 1, wherein the pixel unit further comprises a second undoped semiconductor layer, a first barrier layer, a first superlattice layer, and a second superlattice layer sequentially disposed between the first semiconductor layer and the quantum well light-emitting layer;
the display chip further comprises a second transparent conductive layer located on one side of the first semiconductor layer facing away from the second semiconductor layer, and a microlens located on one side of the second transparent conductive layer facing away from the first semiconductor layer.

14. A method for manufacturing a display chip, comprising:
forming a base;
forming a pixel unit on one side of the base, wherein the pixel unit comprises a first semiconductor layer, a quantum well light-emitting layer and a second semiconductor layer sequentially disposed on the side of the base; one of the first semiconductor layer and the second semiconductor layer is a n-type semiconductor layer, and the other one of the first semiconductor layer and the second semiconductor layer is a p-type semiconductor layer; wherein a cross-sectional area of the pixel unit is gradually increased in a direction toward the base; and
removing the base.

15. The method for manufacturing the display chip according to claim 14, wherein the forming of the pixel unit at one side of the base comprises:
forming a first semiconductor layer on one side of the base;
forming a quantum well light-emitting layer on one side of the first semiconductor layer facing away from the base;
forming a second semiconductor layer on one side of the quantum well light-emitting layer facing away from the base; and
etching the second semiconductor layer, the quantum well light-emitting layer and the first semiconductor layer to form the pixel unit.

16. The method for manufacturing the display chip according to claim 15, wherein the first semiconductor layer comprises a heavily doped semiconductor layer and a lightly doped semiconductor layer positioned between the heavily doped semiconductor layer and the quantum well light-emitting layer;
the etching the second semiconductor layer, the quantum well light-emitting layer and the first semiconductor layer to form the pixel unit comprises:
etching the second semiconductor layer, the quantum well light-emitting layer and the lightly doped semiconductor layer to form an initial pixel unit, and exposing part of the heavily doped semiconductor layer;
forming a passivation layer on one side of the initial pixel unit facing away from the base, and the passivation layer covers a side wall of the initial pixel unit and the exposed part of the heavily doped semiconductor layer;
forming a second reflective layer on a surface of the passivation layer; and
etching the second reflective layer, the passivation layer and the heavily doped semiconductor layer on a peripheral side of the initial pixel unit to form the pixel unit.

17. The method for manufacturing the display chip according to claim 14, wherein before the removing said base, further comprising:
bonding one side of the pixel unit facing away from the base, with a base plate.

18. The method for manufacturing the display chip according to claim 17, wherein the pixel unit further comprises a first transparent conductive layer and a first reflective layer sequentially disposed on one side of the second semiconductor layer facing away from the quantum well light-emitting layer, and the base plate comprises a second bonding structure;
bonding one side of the pixel unit facing away from the base, with a base plate comprises:
forming a first dielectric layer on one side of the first reflective layer facing away from the first transparent conductive layer;
forming a first bonding structure penetrating through the first dielectric layer and is connected with the first reflective layer; and
bonding the pixel unit and the base plate through the first bonding structure and the second bonding structure.

19. The method for manufacturing the display chip according to claim 18, wherein the first bonding structure comprises a first bonding layer and a first bonding protective layer;
the forming a first bonding structure penetrating through the first dielectric layer and connected with the first reflective layer comprises:
forming an opening penetrating through the first dielectric layer;
forming the first bonding protective layer on a side wall of the opening;
forming the first bonding layer connected with the first reflective layer in the opening.

20. The method for manufacturing the display chip according to claim 14, wherein after the removing the base, the method further comprising:
forming a second transparent conductive layer on one side of the pixel unit facing away from the second semiconductor layer; and
forming a micro lens on one side of the second transparent conductive layer facing away from the pixel unit.
